(19) United States
(12) Patent Application Publication
(10) Pub. No.: US 2009/0020848 A1
(43) Pub. Date: Jan. 22, 2009

(54) HIGH-FREQUENCY TRANSISTOR

(76) Inventors: Naoko ONO, Tokyo (JP); Masahiro Hosoya, Kawasaki-shi (JP); Yoshiaki Yoshihara, Yokohama-shi (JP)

Correspondence Address: FINNEGAN, HENDERSON, FARABOW, GARRETT & DUNNER;LLP, 901 NEW YORK AVENUE, NW, WASHINGTON, DC, 20001-4413, US

(21) Appl. No.: 12/050,231

(22) Filed: Mar. 18, 2008

(30) Foreign Application Priority Data
Jul. 6, 2007 (JP) 2007-178949

(51) Int. Cl. H01L 29/00

(52) U.S. Cl. 257/522; 257/E29.001

(57) ABSTRACT

A high-frequency transistor includes an intrinsic region provided to form an active element on the substrate, plural source and drain fingers alternately located with each other in the intrinsic region in parallel, each including a strip-form interconnect metal layer and contacts formed thereon, plural gate fingers respectively formed between the source and drain fingers and each gate finger including a strip-form gate semiconductor layer, a connecting region provided on the substrate adjacent to and outside of the intrinsic region, plural gate connection semiconductor layers provided in the connecting region according to groups of the gate fingers, each group including some gate fingers adjacent to each other, each gate connection semiconductor layer being connected to end portions of the some gate fingers, and gate connection interconnect metal layers respectively formed on the gate connection semiconductor layers connected thereto through third contacts.

### CROSS-REFERENCE TO RELATED APPLICATIONS

This application is based upon and claims the benefit of priority from prior Japanese Patent Application No. 2007-178949, filed Jul. 6, 2007, the entire contents of which are incorporated herein by reference.

### BACKGROUND OF THE INVENTION

1. Field of the Invention

The present invention relates to a multi-finger high-frequency transistor that is formed in a semiconductor chip for a microwave band or a millimeter-wave band.

2. Description of the Related Art

The number of communication lines must be urgently increased because of a sudden growth of demand in an information communication field in recent years. Therefore, achieving practical use of a system using a microwave/millimeter-wave band which has not been conventionally often used is carried out at a high pace.

In a high-frequency circuit section used in this type of system, having excellent electrical characteristics and a small size is demanded. Considering a reduction in a size of the high-frequency circuit section, integrating necessary circuits as much as possible is effective. That is, realizing a microwave integrated circuit (MIC) or realizing a monolithic microwave integrated circuit (MMIC) is effective.

As an example of advancing realization of an MMIC, a multi-finger MOSFET has been proposed (see, e.g., JP-A 2002-299351 [KOKAI]). In this MOSFET, a plurality of gate fingers using a gate polysilicon layer are provided in an intrinsic region in parallel, a bar-shaped gate connection polysilicon layer that is continuous in a direction vertical to the gate fingers is provided outside the intrinsic layer to bundle the gate fingers, and a metal interconnect layer that is connected with the gate connection polysilicon layer through a plurality of contacts is provided on the gate connection polysilicon layer.

However, this structure has a problem that an area of the gate connection polysilicon layer outside the intrinsic layer is large and a parasitic shunt capacitance of the MOSFET is increased. Further, a connecting portion between the gate polysilicon layer and the gate connection polysilicon layer is deformed due to processing, and a width of the gate polysilicon layer is increased. Therefore, the width of the gate polysilicon layer is increased in a region close to the gate connection polysilicon layer, which disadvantageously leads to an increase in a parasitic shunt capacitance and nonuniformity of a gate length.

Furthermore, in order to avoid an increase in a parasitic shunt capacitance, there is a structure where gate connection polysilicon layers are individually provided outside an intrinsic region in accordance with respective gate fingers, one contact is located with respect to one finger, and the gate connection polysilicon layers are connected with an interconnect metal layer.

However, in this structure, since one contact is provided per finger, when a contact has a connection failure, a gate finger associated with this contact does not function as an MOSFET. Therefore, there is a problem of a reduction in a production yield ratio.

Therefore, realization of a high-frequency transistor that can reduce a parasitic capacitance for gate fingers to improve high-frequency characteristics and also improve a yield ratio has been demanded.

### BRIEF SUMMARY OF THE INVENTION

According to one aspect of the invention, there is provided a high-frequency transistor, which includes:

a semi-insulative substrate;

an intrinsic region provided to form an active element on the semi-insulative substrate;

a plurality of source fingers located in the intrinsic region in parallel, each of the plurality of source fingers including a strip-form interconnect metal layer and a plurality of first contacts formed thereon;

a plurality of drain fingers located in the intrinsic region in parallel and alternately located with the source fingers, each of the drain fingers including a strip-form interconnect metal layer and a plurality of second contacts located thereon;

a plurality of gate fingers respectively formed between the source fingers and the drain fingers and each including a strip-form gate semiconductor layer;

a connecting region provided on the semi-insulative substrate to be adjacent to the intrinsic region outside the intrinsic region;

a plurality of gate connection semiconductor layers provided in the connecting region in accordance with groups of the gate fingers, each of the groups including some of the gate fingers adjacent to each other, each of the plurality of gate connection semiconductor layers being connected to end portions of the some of the gate fingers adjacent to each other; and

gate connection interconnect metal layers respectively formed on the plurality of gate connection semiconductor layers and connected to the plurality of gate connection semiconductor layers through a plurality of third contacts.

### BRIEF DESCRIPTION OF THE SEVERAL VIEWS OF THE DRAWING

FIG. 1 is a plan view showing an outline structure of a high-frequency MOSFET according to a first embodiment;

FIG. 2 is a perspective view showing the outline structure of the high-frequency MOSFET according to the first embodiment;

FIG. 3A is a plan view showing how a width of each gate finger is expanded at a connecting portion between the gate finger and a gate connection semiconductor layer in a conventional high-frequency MOSFET;

FIG. 3B is a plan view showing how a width of each gate finger is expanded in the high-frequency MOSFET according to the first embodiment;

FIG. 4 is a table showing a relationship between the number of fingers (Nf) and an input shunt capacitance (C11) when a total gate width is fixed in the first embodiment in comparison with that in a conventional technology;

FIG. 5 is a view showing FIG. 4 in the form of a graph;

FIG. 6 is a table showing a relationship between the number of fingers (Nf) and an input shunt capacitance (C11) when a gate width per finger is fixed in the first embodiment in comparison with that in the conventional technology;

FIG. 7 is a view showing FIG. 5 in the form of a graph;

FIG. 8 is a table showing a relationship of a cutoff frequency (fT) with respect to a ratio of a gate width per finger and the number of fingers (Nf) when a total gate width is fixed in the first embodiment in comparison with that in the conventional technology;

FIG. 9 is a table showing total gate width dependence of the cutoff frequency (fT);

FIG. 10 is a plan view showing a modification of the high-frequency MOSFET according to the first embodiment;

FIG. 11 is a plan view showing another modification of the high-frequency MOSFET according to the first embodiment;

FIG. 12 is a plan view showing an outline structure of a high-frequency MOSFET according to a second embodiment;

FIG. 13 is a plan view showing a modification of the high-frequency MOSFET according to the second embodiment;

FIG. 14 is a perspective view showing an outline structure of a high-frequency MOSFET according to a third embodiment; and

FIG. 15 is a plan view showing an outline structure of a high-frequency MOSFET according to a fourth embodiment.

### DETAILED DESCRIPTION OF THE INVENTION

Embodiments according to the present invention will now be explained hereinafter with reference to the accompanying drawings.

### First Embodiment

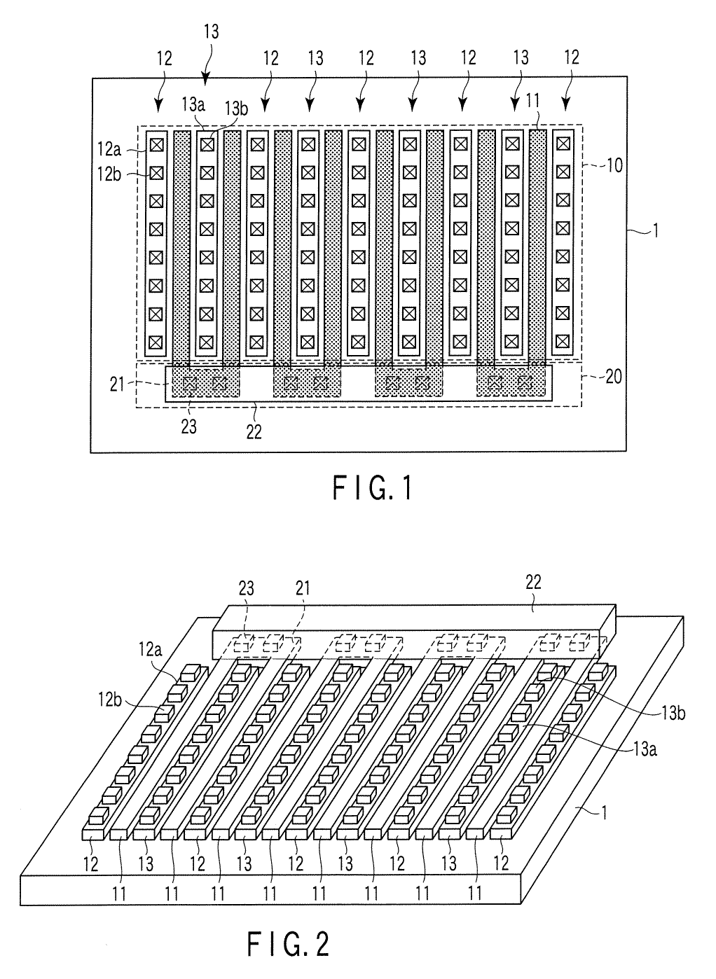

FIGS. 1 and 2 are views for explaining an outline structure of a multi-finger high-frequency MOSFET according to a first embodiment.

In the drawing, reference number 10 denotes an intrinsic region on a semi-insulative substrate (e.g., a GaAS substrate) 1 where an element is formed, and a plurality of gate fingers 11, source fingers 12, and drain fingers 13 are aligned and formed in this intrinsic region 10. It is to be noted that at least four gate fingers 11 must be provided to obtain an effect of this embodiment as will be explained later.

Each source finger 12 and each drain finger 13 are alternately arranged, and one gate finger 11 is placed between the source finger 12 and the drain finger 13 adjacent to each other. The source finger 12 is formed of a strip-form interconnect metal layer 12a and contacts 12b, and the drain finger 13 is likewise formed of a strip-form interconnect metal layer 13a and contacts 13b. As a contact shape, any one of a circular shape, a square shape, a regular polygonal shape, an elliptic shape, a rectangular shape, and others can be adopted. The gate finger 11 is formed of a strip-form gate polysilicon layer (a gate semiconductor layer). It is to be noted that contacts and an interconnect metal layer are not present on the gate polysilicon layer of the gate finger 11 in the intrinsic region 10.

It is to be noted that a pattern width of the gate polysilicon of the gate finger can be set to 0.5 μm or below, and a pitch of the gate polysilicon layer of the gate finger 11 can be set to approximately 1.4 μm or below. Further, a width of each of the interconnect metal layer 12a of the source finger 12 and the interconnect metal 13a of the drain finger 13 can be set to approximately 0.6 μm or below.

In a connecting region 20 outside the intrinsic region 10 on the semi-insulative substrate 1, gate polysilicon layers (gate connection semiconductor layers) 21 each of which bundles the gate fingers 11 to be connected are provided. This gate polysilicon layer 21 has a rectangular pattern that is long in a direction perpendicular to the gate fingers 11, and is provided every two gate fingers 11 to be separated from the other gate polysilicon layers 21. Furthermore, each gate polysilicon layer 21 is connected with one side end portion of each gate finger 11 to bundle the two gate fingers 11.

It is to be noted that the gate polysilicon layer for the gate finger 11 and the gate connection gate polysilicon layer 21 are the same layer, and they are simultaneously formed by patterning the same material. Moreover, the gate polysilicon layer of each gate finger 11 is partially extended to the outside of the intrinsic region 10, and this extended portion is connected with the gate polysilicon layer 21.

A gate connection interconnect metal layer 22 is formed to get across the plurality of gate polysilicon layers 21, and this interconnect metal layer 22 is connected with the gate polysilicon layers 21 through a plurality of contacts 23. More specifically, the interconnect metal layer 22 is connected with one gate polysilicon layer 21 through two contacts 23.

The one-side end portions of the gate finger narrow sides are bundled every two gate fingers 11 adjacent to each other by using each gate polysilicon layer 21 in this manner, and the contacts are placed on each bundled portion to connect each gate polysilicon layer 21 with the interconnect metal layer 22.

When regarding the portion of each gate finger 11 extended to the connecting region 20 as a part of the gate polysilicon layer 21 for gate connection, the gate polysilicon layer 21 bundling the two gate fingers 11 has a U-like shape. Additionally, the connecting portion bundling the gate fingers 11 has a protruding portion in the width direction which has an angle of approximately 90 degrees (270 degrees) on one side, and has a flat side surface on the other side which linearly overlaps (which is flush with) a side surface of the gate finger 11 without a protrusion in the width direction, namely, the connecting portion has an L-like plane shape. Further, a width of the gate polysilicon layer 21 that bundles the gate fingers is larger than a width of the gate finger (the gate polysilicon layer) 11 in the intrinsic region 10.

As explained above, according to this embodiment, since the gate polysilicon layer 21 that connects the gate fingers 11 is separated from another gate polysilicon layer 21 every two gate fingers 11, an area of the entire gate polysilicon layer 21 can be reduced. Therefore, a parasitic shunt capacitance (C11) of the MOSFET can be reduced as compared with a conventional structure. Furthermore, the gate fingers 11 and the gate polysilicon layer 21 are located in such a manner that one side surface of each gate finger 11 is flash with one side surface of the gate polysilicon layer 21, high-frequency characteristic degradation factors, e.g., nonuniformity of a gate length near the connecting portion of each gate finger 11 or an increase in a parasitic shunt capacitance, can be reduced.

Here, reasons for enabling suppression of nonuniformity of the gate length at the connecting portion of each gate finger 11 and achieving a reduction in the parasitic shunt capacitance will be explained below.

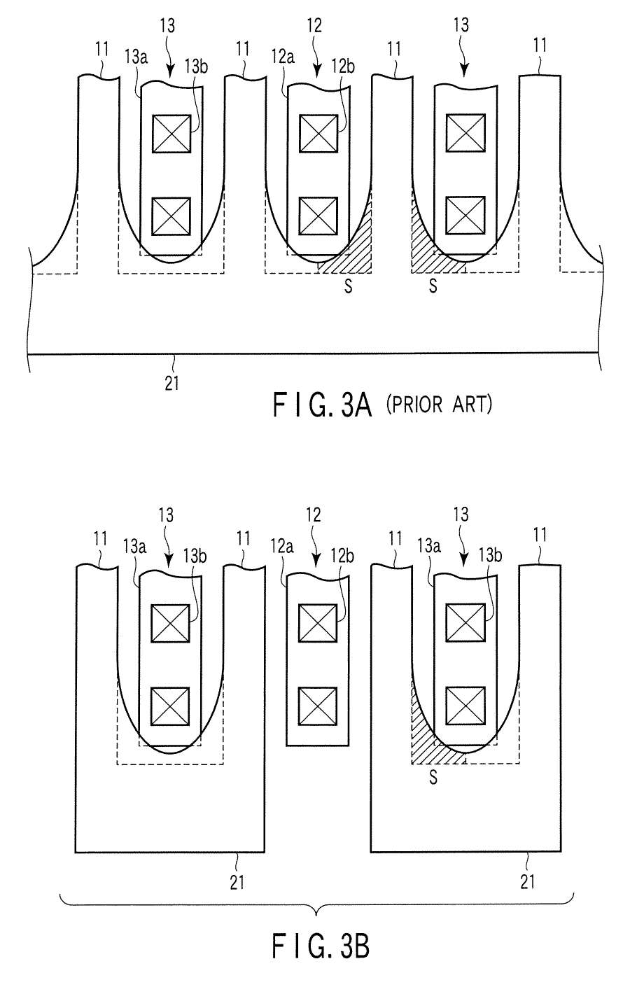

In a conventional structure, as shown in FIG. 3A, each gate finger 11 and a polysilicon layer 21 have an angle of 90 degrees in a connecting portion of each gate finger 11 and the gate polysilicon layer 21, and hence each angular portion is tapered with respect to a design pattern to thicken each gate finger 11 in the connecting portion. Therefore, an area of one gate finger 11 is increased by an amount corresponding to an area 2S indicated by a broken line in FIG. 3A, and this leads to an increase in a capacitance and nonuniformity of a gate length. It is to be noted that an amount of an increase in a parasitic capacitance (C11) per taper is, e.g., 0.025 fF.

On the other hand, in this embodiment, as shown in FIG. 3B, since one side surface of each gate finger 11 is flush with the side surface of the gate polysilicon layer 21, an increased amount of an area of the gate finger 11 in the connecting portion is S which is half of that in FIG. 3B. Therefore, an increase in a capacitance can be reduced to half, and a factor of nonuniformity of a gate length can be decreased. That is, in the structure according to this embodiment, the number of tapered end portions of the gate fingers 11 can be reduced to approximately half of that in the conventional structure, and a high-frequency MOSFET having a high cutoff frequency (fT), i.e., characteristics suitable for a high frequency can be realized.

Furthermore, in this embodiment, in the connecting portion 20 that bundles every two gate fingers 11, the number of the contacts 23 that connect the gate polysilicon layer 21 with the interconnect metal layer 22 is two. When the number of the contact is one, since the two gate fingers do not function as an MOSFET when this single contact has a connection failure, a production yield ratio of the MOSFET is lowered. Providing the two contacts to the one gate polysilicon layer like this embodiment enables increasing the production yield ratio.

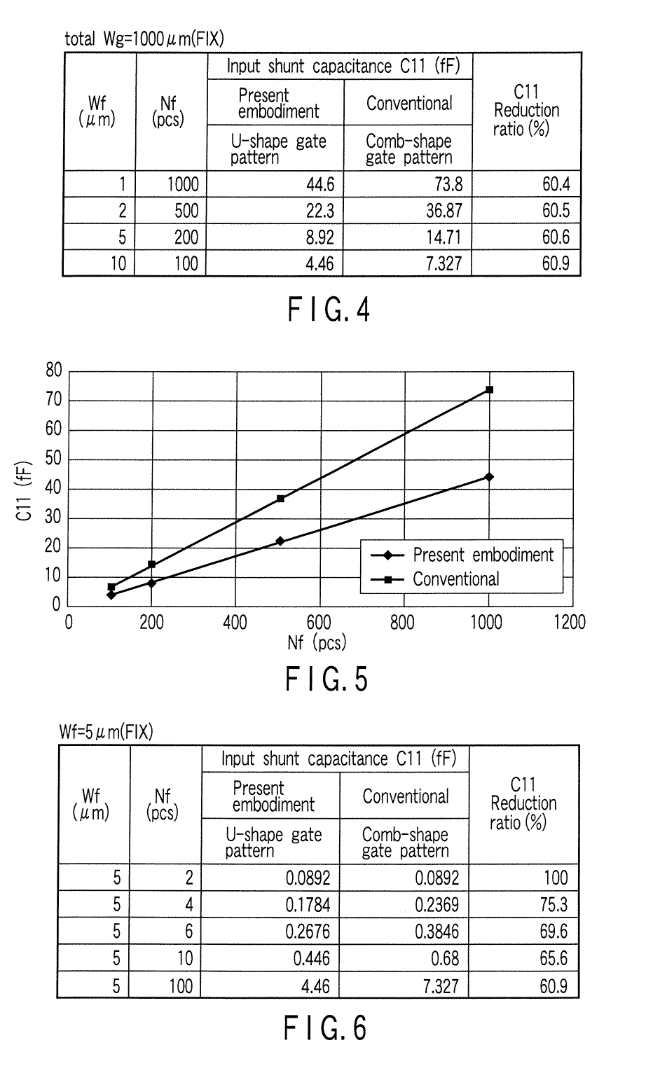

An effect according to this embodiment will now be explained based on specific data. First, FIG. 4 shows a layout dependence evaluation result of the parasitic component input shunt capacitance C11 of the MOSFET. This table shows a value of the input shunt capacitance (C11) as a parasitic component in a conventional structure (a comb shape) in which gate fingers are collectively bundled in comparison with that in the structure according to this embodiment. However, a total gate width (Wg) of the MOSFET is fixed to 1 mm, and a ratio of a gate width (Wf) per unit gate finger and the number of the fingers (Nf) is a variable. Further, FIG. 5 shows a relationship between the number of the fingers (Nf) and the input shunt capacitance (C11) based on this FIG. 4.

Comparing with the conventional structure, the input shunt capacitance (C11) is approximately 60% in the structure according to this embodiment. That is, the structure according to this embodiment is a structure that can reduce the input shunt capacitance (C11) as a parasitic capacitance which is a factor degrading high-frequency characteristics.

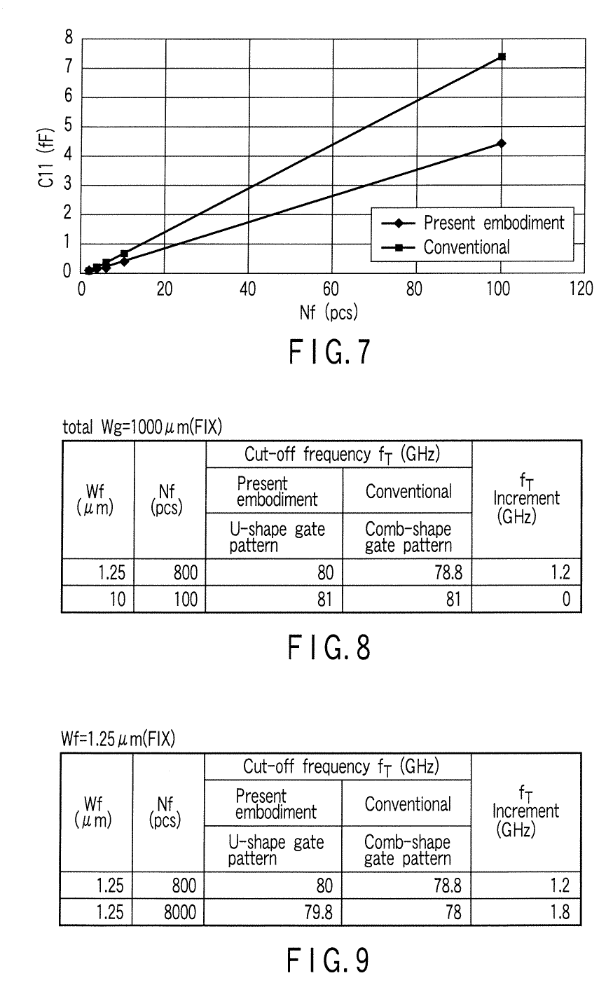

FIG. 6 shows a total gate width dependence evaluation result of the parasitic component input shunt capacitance (C11) of the MOSFET. In this table, a value of the input shunt capacitance (C11) as a parasitic component when Wf is fixed to 5 μm and Wg is determined as a variable by changing Nf in the structure according to this embodiment is compared that in the conventional structure having a collectively bundled gate polysilicon layer. Furthermore, FIG. 7 shows a relationship between the number of the fingers (Nf) and the input shunt capacitance (C11) based on this FIG. 6.

It can be understood from FIG. 6 that the effect of reducing the input shunt capacitance (C11) is increased in the structure according to this embodiment when Nf is large and Wg is large as compared with the conventional structure. That is, the structure according to this embodiment is a structure that can reduce the input shunt capacitance as a parasitic component serving as a factor degrading high-frequency characteristics. In particular, this is a structure suitable for a transistor with a large Wg, e.g., a high-frequency power MOSFET.

FIG. 8 shows a layout dependence evaluation result of a cutoff frequency fT of the MOSFET. In this table, the cutoff frequency (fT) in the conventional structure having the collectively bundled gate polysilicon layer is compared with that in the structure according to this embodiment. However, a total gate width (Wg) of the MOSFET is fixed to 1 mm, and a ratio of a gate width (Wf) per unit gate finger and the number of the fingers is a variable.

It can be understood from FIG. 8 that fT can be increased in the structure according to this embodiment when Wf is small as compared with the conventional structure. That is, this embodiment has a structure that can increase fT which is an important item representing a high-frequency performance of the MOSFET. In particular, a layout of the MOSFET having the small Wf has a significant effect when a millimeter-wave operating frequency is high.

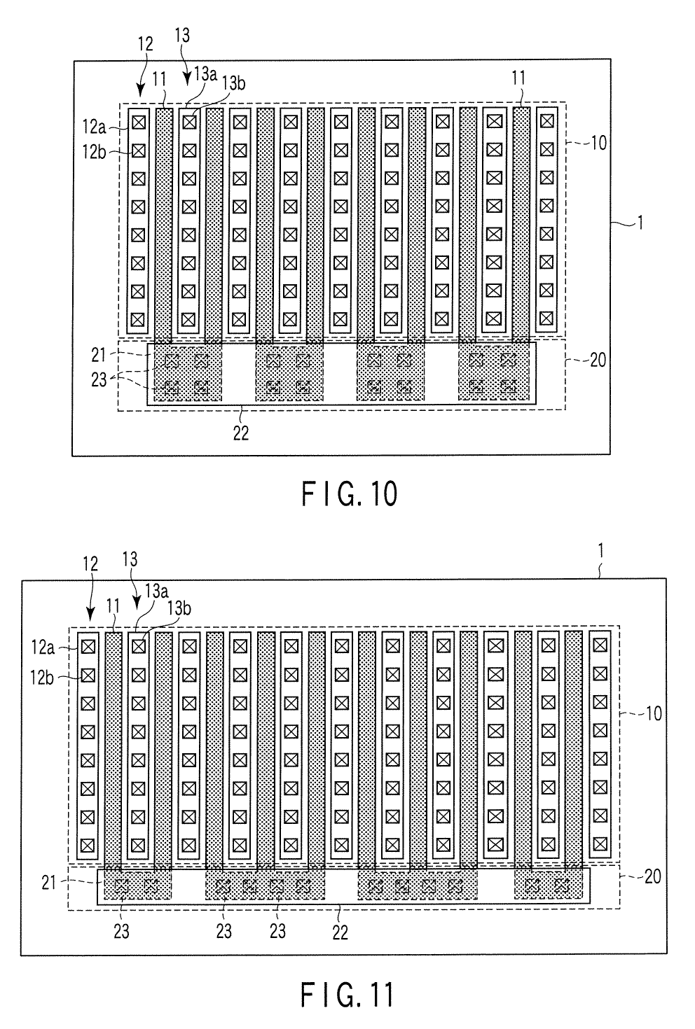

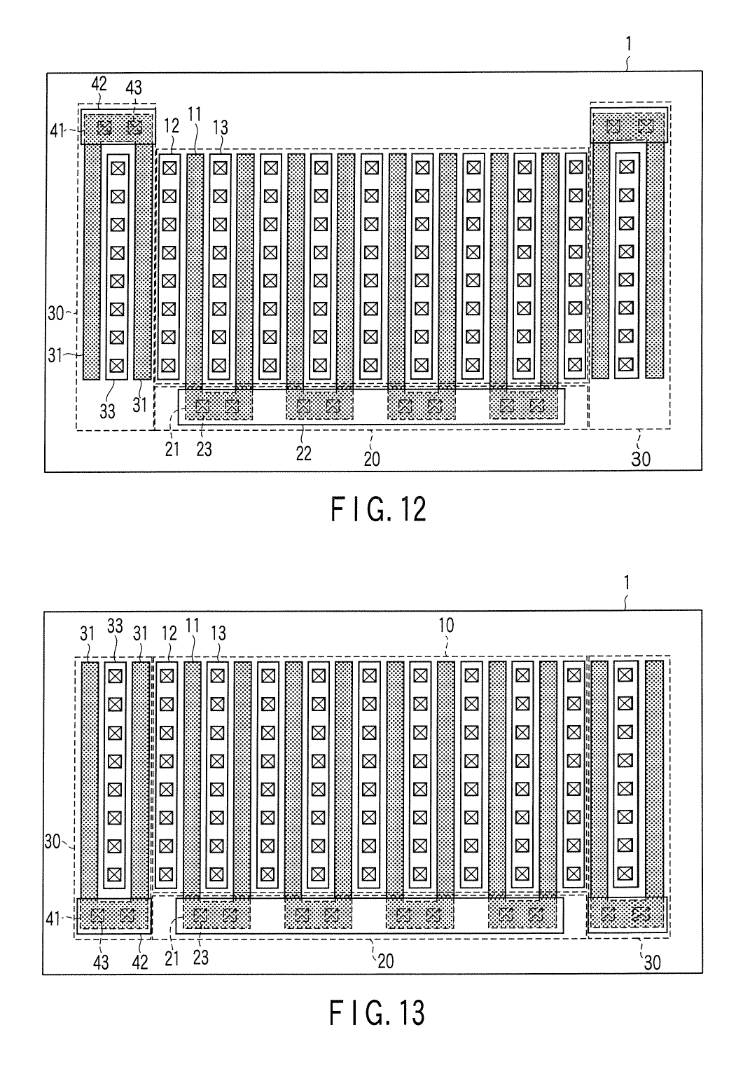

FIG. 9 shows a total gate width dependence evaluation result of the cutoff frequency fT of the MOSFET. In this table, a value of the cutoff frequency (fT) in the conventional structure having the collectively bundled gate polysilicon layer is compared with that in the structure according to this embodiment when Wf is fixed to 1.25 μm and Wg is determined as a variable by changing Nf. It can be understood from FIG. 9 that the MOSFET in the structure according to this embodiment can increase fT when Nf is large and Wg is also large as compared with the conventional structure.

That is, the structure according to this embodiment can increase fT as an important item representing a high-frequency performance of the MOSFET. In particular, this is a structure suitable for a transistor having large Wg, e.g., a high-frequency power MOSFET. For example, adopting the structure according to this embodiment for an MOSFET in which Wg is 10 mm and an output power PldB is 20 dBm when 1-dB compression is effected on an output side enables improving fT by 1.8 GHz.

Considering a maximum available power-gain (MAG) as an important item representing a high-frequency performance of the MOSFET, adopting the structure according to this embodiment corresponds to improving MAG by approximately 0.2 to 1.6 dB.

As explained above, according to this embodiment, the input side parasitic capacitance of the MOSFET can be reduced. Moreover, a tolerance of the gate length in the MOSFET intrinsic region can be reduced. Therefore, the MOSFET having the high cutoff frequency, the large MAG, and excellent high-frequency characteristics can be realized.

It is to be noted that the two contacts 23 are provided at each gate connection semiconductor layer 21 portion in this embodiment, but a width of the gate connection semiconductor layer 21 can be increased to provide more (e.g., four) contact 23. In the gate connecting region 20, the gate polysilicon layer 21 is placed far from the substrate as compared with the gate polysilicon layer of the gate finger 11, and an increase in the parasitic capacitance involved by an increase in an area of the gate polysilicon layer 21 is small. Therefore, a demerit caused due to an increase in the area of the gate polysilicon layer 21 is small, but a contact resistance reducing effect obtained owing to an increase in the number of contacts is large.

Moreover, the number of the gate fingers 11 to be connected in one gate polysilicon layer 21 is not necessarily restricted to two. Every three gate fingers 11 may be bundled, or every four gate fingers 11 may be bundled. Additionally, as shown in FIG. 11, two figures, e.g., two and three, may be used as the number of the gate fingers 11 to be bundled.

### Second Embodiment

FIG. 12 is a plan view showing an outline structure of a multi-finger high-frequency MOSFET according to a second embodiment. It is to be noted that like reference numbers denote parts equal to those in FIG. 1, thereby omitting a detailed explanation thereof.

This embodiment is different from the first embodiment in that dummy gate regions 30 each having dummy gates located therein are provided outside an intrinsic region portion 10. That is, dummy gates 31 each of which does not have a function as a gate of an MOSFET but has the same shape as a gate finger are located at the same intervals as those of the gate fingers 11 on both sides of the plurality of gate fingers connected in parallel and located in the intrinsic region 10 of the MOSFET. Here, the two dummy gates 31 are located in each dummy gate region 30.

The two dummy gates 31 which are adjacent to each other in each dummy gate region 30 are connected with a gate polysilicon layer 41 at an end opposite to connected ends of the gate fingers 11. Further, the gate polysilicon layer 41 is connected with an interconnect metal layer 42 having a ground potential through contacts 43. Furthermore, in each dummy gate region 30, a dummy drain finger 33 is provided between the dummy gates 31 adjacent to each other in order to approximate an internal pattern to the intrinsic region portion 10.

As explained above, according to the second embodiment, by providing the dummy gates 31 in addition to the structure according to the first embodiment, characteristics of the plurality of gate fingers 11 located in the intrinsic region portion 10 of the MOSFET including the fingers at the ends can be uniformed. Therefore, the same effect as that of the first embodiment can be obtained, and element characteristics can be further improved.

It is to be noted that the dummy gates 31 are connected with the gate polysilicon layer 41 on the side opposite to the connected ends of the gate fingers 11 in order to connect the dummy gates 31 in this embodiment, but the dummy gates may be connected with the gate polysilicon layer 41 on the same side as the gate polysilicon layers 21. Moreover, the number of the gate fingers 11 to be connected is not necessarily restricted two, and every three or four gate fingers 11 may be bundled.

### Third Embodiment

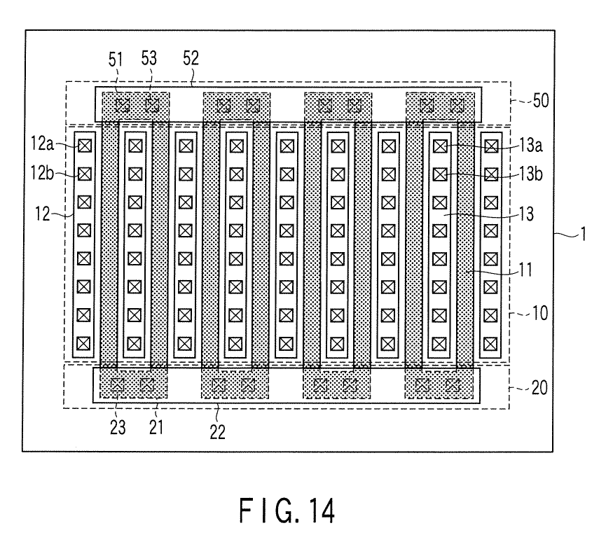

FIG. 14 is a plan view showing an outline structure of a multi-finger high-frequency MOSFET according to a third embodiment. It is to be noted that like reference numbers denote parts equal to those in FIG. 1, thereby omitting a detailed explanation thereof.

This embodiment is different from the first embodiment in that gate fingers 11 are connected on both side ends rather than connected on one side end alone. That is, in this embodiment, not only a connecting region 20 is provided on a lower side of an intrinsic region portion 10 but also a connecting region 50 is provided on an upper side of the same. A plurality of gate polysilicon layers 51 for connection of the gate fingers 11 are formed in the upper connecting region 50 like the lower connecting region 20, and each gate polysilicon layer 51 is connected with an interconnect metal layer 52 through contacts 53.

When such a structure is adopted, not only one side end but also both side ends of the gate fingers 11 are connected with the interconnect metal layers 22 and 55, thereby further reducing an unnecessary resistance component inserted into each gate of the MOSFET in series. Therefore, the same effect as that of the first embodiment can be obtained, and element characteristics can be further improved.

Additionally, in this embodiment, the number of the gate fingers 11 to be connected is not necessarily restricted to two, and it can be arbitrarily changed. Further, dummy gates may be provided like the second embodiment.

### Fourth Embodiment

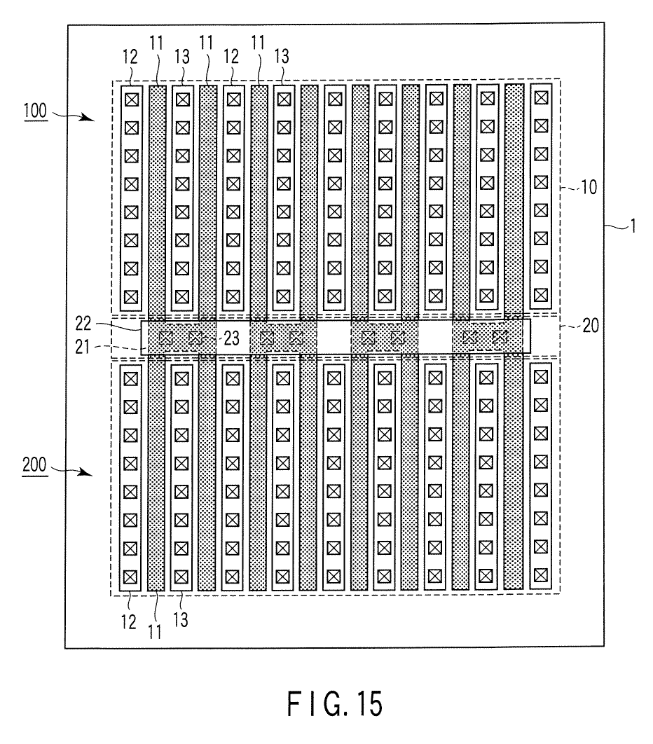

FIG. 15 is a plan view showing an outline structure of a multi-finger high-frequency MOSFET according to a fourth embodiment of the present invention. It is to be noted that like reference numbers denote parts equal to those in FIG. 1, thereby omitting a detailed explanation thereof.

This embodiment is different from the first embodiment in that a plurality of cell regions each having respective fingers 11, 12, and 13 arranged in parallel are provided.

The gate fingers 11, the source fingers 12, and the drain fingers 13 formed in the intrinsic region portion 10 depicted in FIG. 1 constitute a first cell region 100, and a second cell region 200 having the same structure as this cell region 100 is provided with a fixed distance from this cell region 100. Further, the respective corresponding fingers are arranged to be linearly aligned in the first and second cell regions 100 and 200. That is, the first and second cell regions 100 and 200 have the same number and the same pitch of the gate fingers, and the gate fingers forming respective corresponding pairs are arranged in such a manner that their narrow sides face each other and their side surfaces in a longitudinal direction are linearly placed.

A connecting region 20 is located between the first cell region 100 and the second cell region 200. Gate polysilicon layers 21, an interconnect metal layer 200, and contacts 23 are provided in the connecting region 20 like the first embodiment. Further, two gate fingers 11 in the first cell region 100 and two gate fingers 11 in the second cell region 200 are connected with one gate polysilicon layer 21. That is, the four gate fingers 11 are connected with one gate polysilicon layer 21.

Here, considering a portion of each gate finger 11 extended to the connecting region 20 as a part of the gate polysilicon layer 21 for gate connection, a pattern of the gate polysilicon layer 21 bundling the four gate fingers 11 has an H-like shape or an H shape in which corners of a bundling portion are rounded. Paying attention to one cell region, in the vicinity of a connecting part of the portion bundling the gate fingers, there is a structure including a protruding portion in a width direction which has an angle of approximately 90 degrees (270 degrees) on one side and including a portion which is flush with a side surface of the gate finger 11 without a protrusion in the width direction on the other side, i.e., an L-like shape. Therefore, like the first embodiment, the number of tapered end portions of the gate fingers 11 can be reduced to approximately half of that in the conventional structure.

As explained above, according to this embodiment, even when the plurality of cell regions are arranged, a parasitic capacitance with respect to the gate fingers can be reduced to improve high-frequency characteristics, thereby enhancing a yield ratio. In case of an MOSFET having a large total gate width, dividing a cell into at least two unit cells like this embodiment enables avoiding a problem that a length of a narrow side is extremely different from a length of a wide side in a shape of the entire MOSFET or that a gate width per unit finger becomes extremely large, thereby decreasing an unnecessary resistance component which adheres to each gate of the MOSFET in series.

Furthermore, in this embodiment, the number of the gate fingers 11 to be connected is not necessarily restricted to two, and it can be appropriately changed. Moreover, dummy gates may be provided like the second embodiment. Additionally, the number of the cell regions is not restricted to two, and more cell regions may be arranged along the longitudinal direction of the gate fingers.

(Modification)

It is to be noted that the present invention is not restricted to each of the foregoing embodiments. Although the example using the MOSFET as a transistor has been explained in the embodiments, the present invention can be applied to an example using any other transistor, e.g., a complementary MOSFET (CMOS), a bipolar junction transistor (BJT), a high-electron-mobility transistor (HEMT), a hetrojunction bipolar transistor (HBT), or a metal-semiconductor field-effect transistor (MESFET).

Further, the gate semiconductor layer or the gate connection semiconductor layer is not necessarily restricted to the polysilicon layer, any layer that can be formed on a gate insulating film suffices, and various kinds of semiconductor materials can be used. Furthermore, the number of the gate fingers located in one intrinsic region, the number of the contacts provided on each source finger and each drain finger, and others can be appropriately changed in accordance with specifications.

According to the present invention, a parasitic capacitance with respect to the gate fingers can be reduced to improve high-frequency characteristics, thereby enhancing a yield ratio.

Additional advantages and modifications will readily occur to those skilled in the art. Therefore, the invention in its broader aspects is not limited to the specific details and representative embodiments shown and described herein. Accordingly, various modifications may be made without departing from the spirit or scope of the general inventive concept as defined by the appended claims and their equivalents.

What is claimed is:

1. A high-frequency transistor comprising:
a semi-insulative substrate;
an intrinsic region provided to form an active element on the semi-insulative substrate;
a plurality of source fingers located in the intrinsic region in parallel, each of the plurality of source fingers including a strip-form interconnect metal layer and a plurality of first contacts formed thereon;
a plurality of drain fingers located in the intrinsic region in parallel and alternately located with the source fingers, each of the drain fingers including a strip-form interconnect metal layer and a plurality of second contacts located thereon;
a plurality of gate fingers respectively formed between the source fingers and the drain fingers and each including a strip-form gate semiconductor layer;
a connecting region provided on the semi-insulative substrate to be adjacent to the intrinsic region outside the intrinsic region;
a plurality of gate connection semiconductor layers provided in the connecting region in accordance with groups of the gate fingers, each of the groups including some of the gate fingers adjacent to each other, each of the plurality of gate connection semiconductor layers being connected to end portions of the some of the gate fingers adjacent to each other; and
gate connection interconnect metal layers respectively formed on the plurality of gate connection semiconductor layers and connected to the plurality of gate connection semiconductor layers through a plurality of third contacts.

2. The high-frequency transistor according to claim 1, wherein each of the gate connection semiconductor layers has a rectangular pattern extended in a direction perpendicular to the plurality of gate fingers, and
each of the gate semiconductor layers has an extended portion partially extended to the outside of the intrinsic region, and the extended portion is connected to corresponding one of the gate connection semiconductor layers.

3. The high-frequency transistor according to claim 2, wherein every two of the plurality of gate fingers adjacent to each other are connected with the corresponding one of the gate connection semiconductor layers, and
one side surface of the extended portion is connected and flush with one side surface of the gate connection semiconductor layer, and the other side surface of the extended portion is connected with the other side surface of the gate connection semiconductor layer at an angle of 90 degrees.

4. The high-frequency transistor according to claim 1, wherein the gate semiconductor layer included in the gate fingers and the gate connection semiconductor layers are formed of the same semiconductor layer, and formed by patterning the same semiconductor layer.

5. The high-frequency transistor according to claim 1, wherein the gate semiconductor layer and the gate connection semiconductor layers contain polysilicon.

6. The high-frequency transistor according to claim 1, wherein pitches of the source fingers, the drain fingers, and the gate fingers are fixed, respectively.

7. The high-frequency transistor according to claim 1, wherein dummy gates each having the same shape as the gate fingers are located on both outer sides of the intrinsic region in an arranging direction of the source fingers, the drain fingers, and the gate fingers at the same pitch as that of the gate fingers.

8. The high-frequency transistor according to claim 7, further comprising:
a dummy gate connection semiconductor layer connected to one end of the dummy gates;
a dummy interconnect metal layer formed on the dummy gate connection semiconductor layer; and
fourth contacts through which dummy interconnect metal layer electrically connected to the dummy gate connection semiconductor layer having a ground potential.

9. The high-frequency transistor according to claim 1, wherein a pattern width of the gate connection semiconductor layer is larger than a width of the gate finger.

10. A high-frequency transistor comprising:
a semi-insulative substrate;
an intrinsic region to form an active element provided on the semi-insulative substrate;
a plurality of source fingers located in the intrinsic region in parallel, each of the source fingers including a strip-form interconnect metal layer and a plurality of first contacts;
a plurality of drain fingers located in the intrinsic region in parallel and alternately located with the source fingers, each of the drain fingers including a strip-form interconnect metal layer and a plurality of second contacts;
a plurality of gate fingers respectively formed between the source fingers and the drain fingers, each of the gate fingers including a strip-form gate semiconductor layer;
a first connecting region and a second connecting region provided on the semi-insulative substrate on opposed outer sides of the intrinsic region, respectively, to be adjacent to the intrinsic region;
a plurality of first gate connection semiconductor layers provided in the first connecting region in accordance with groups of the gate fingers, each of the groups including some of the gate fingers adjacent to each other, each of the first gate connection semiconductor layers being connected to one end of the some of the gate fingers adjacent to each other;
a plurality of second gate connection semiconductor layers provided in the second connecting region in accordance with the groups of the gate fingers, each of the groups including the some of the gate fingers adjacent to each other, each of the second gate connection semiconductor layers being connected to the other end of the some of the gate fingers adjacent to each other;
a first gate connection interconnect metal layer formed on the first gate connection semiconductor layers and connected to the gate fingers through a plurality of third contacts; and
a second gate connection interconnect metal layer formed on the second gate connection semiconductor layers and connected to the gate fingers through a plurality of fourth contacts.

11. The high-frequency transistor according to claim 10, wherein the gate connection semiconductor layer has a rectangular pattern extended in a direction perpendicular to the gate fingers, and
the gate semiconductor layer has an extended portion partially extended to outside of the intrinsic region, and the extended portion is connected to the gate connection semiconductor layer.

12. The high-frequency transistor according to claim 11, wherein every two of the gate fingers adjacent to each other are connected to each of the gate connection semiconductor layers, and
one side surface of the extended portion is flush with one side surface of the gate connection semiconductor layer, and the other side surface of the extended portion is connected to the other side surface of the gate connection semiconductor layer at an angle of 90 degrees.

13. The high-frequency transistor according to claim 10, wherein the gate semiconductor layer included in the gate fingers and the gate connection semiconductor layers are formed of the same semiconductor layer, and formed by patterning the same semiconductor layer.

14. The high-frequency transistor according to claim 10, wherein pitches of the source fingers, the drain fingers, and the gate fingers are fixed, respectively.

15. A high-frequency transistor comprising:
a semi-insulative substrate;
a first region and a second cell region provided on the semi-insulative substrate to be adjacent to each other and each provided to form an active element; and
a connecting region formed on the semi-insulative substrate between the first cell region and the second cell region,
the first cell region including:
a plurality of first source fingers and first drain fingers, each of which is formed of a strip-form first interconnect metal layer and first contacts formed thereon and which are alternately located in parallel; and
a plurality of first gate fingers which are located between the first source fingers and the first drain fingers, respectively, and each formed of a strip-form gate semiconductor layer,
the second cell region including:
a plurality of second source fingers and second drain fingers, each of which is formed of a strip-form second interconnect metal layer and second contacts formed thereon and which are alternately located in parallel,
a plurality of second gate fingers which are located between the second source fingers and the second drain fingers, respectively, and each formed of a strip-form second gate semiconductor layer and second contacts formed thereon, corresponding one of the first and second source fingers, the first and second drain fingers and the first and second gate fingers in the first cell region and the second cell region being formed to be linearly aligned, and
the connecting region including:
a plurality of gate connection semiconductor layers which are separately provided in accordance with N (N≧2) gate fingers in the first cell region and the second cell region, each of which is connected to one end of the N gate fingers in the first cell region and the second cell regions, and one end of corresponding N gate fingers in the second cell region and the second cell region connects every 2N gate fingers; and
a gate connection interconnect metal layer continuously formed on the plurality of gate connection semiconductor layers and connected to each of the gate connection semiconductor layers through third gate contacts.

16. The high-frequency transistor according to claim 15, wherein the gate connection semiconductor layer has a rectangular pattern extending in a direction perpendicular to the plurality of first and second gate fingers, and
the gate semiconductor layer has an extended portion partially extended to the outside of the intrinsic region, and the extended portion is connected to the gate connection semiconductor layer.

17. The high-frequency transistor according to claim 16, wherein every two of the plurality of first gate fingers and the plurality of second gate fingers adjacent to each other are connected with each of the gate connection semiconductor layers, respectively, and
one side surface of the extended portion is connected to and flush with one side surface of the gate connection semiconductor layer, and the other side surface of the extended portion is connected to the other side surface of the gate connection semiconductor layer at an angle of 90 degrees.

18. The high-frequency transistor according to claim 15, wherein the gate semiconductor layers included in the gate fingers and the gate connection semiconductor layer are formed of the same semiconductor layer, and formed by patterning the same semiconductor layer.

19. The high-frequency transistor according to claim 15, wherein pitches of the first source fingers, the second source fingers, the first drain fingers, the second drain fingers, the first gate fingers and the second gate fingers are fixed, respectively.
